(19) United States
(12) Patent Application Publication
(10) Pub. No.: US 2020/0162088 A1
(43) Pub. Date: May 21, 2020

(54) Device, System and Method for Digital-to-Analogue Conversion

(71) Applicant: THE UNIVERSITY OF NEWCASTLE, Callaghan (AU)

(72) Inventors: Arnfinn EIELSEN, Callaghan New South Wales (AU); Andrew FLEMING, Merewether New South Wales (AU)

(73) Assignee: The University Of Newcastle, Callaghan (AU)

(21) Appl. No.: 16/339,602

(22) PCT Filed: Oct. 4, 2017
(86) PCT No.: PCT/AU2017/051080

§ 371 Date: Apr. 4, 2019

(30) Foreign Application Priority Data
Oct. 4, 2016 (AU) 2016904022
Jan. 13, 2017 (AU) 2017900097

(51) Int. Cl. H03M 1/06; H03M 1/80; H03F 3/189; H03F 3/45

(52) U.S. Cl. CPC H03M 1/0639; H03M 1/0626; H03F 3/45; H03F 3/189; H03M 1/808

(57) ABSTRACT

Described herein is a device, system and method for digital-to-analogue conversion. One embodiment provides a digital-to-analogue converter device including: a) a first input configured to receive a digital signal to be converted; b) a second input configured to receive a digital dither signal, the digital dither signal having a predefined amplitude; c) a signal combining module that is configured to combine the digital dither signal with the digital signal in the digital domain to define a combined digital signal; and d) a digital-to-analogue converter module that is configured to process the combined digital signal and to output an analogue signal that is an analogue representation of the combined digital signal. The digital-to-analogue converter module has a predefined output amplitude range. The predefined amplitude of the dither signal is at least 1% of the predefined output amplitude range.

### FIELD OF THE INVENTION

The present invention relates generally to signal processing and in particular to a device, system and method for digital to analogue conversion. While some embodiments will be described herein with particular reference to that application, it will be appreciated that the invention is not limited to such a field of use, and is applicable in broader contexts

### BACKGROUND OF THE INVENTION

Any discussion of the prior art throughout the specification should in no way be considered as an admission that such prior art is widely known or forms part of common general knowledge in the field.

Digital-to-analogue conversion is typically based on mapping codes or numbers to specified discrete voltage or current levels. The mechanism which produces a given voltage or current level is referred to as an element. If the physical levels deviate from ideal specified levels, an error is introduced. This error is called element mismatch. The desired elements are typically switched on or off to produce the desired voltage or current level in the output. The switching is imperfect, and causes glitches, which are high-frequency disturbances.

Element mismatch is typically quantified using the integral non-linearity (INL), and the standard definition is:

$$INL ( k ) {=}^{△} \frac{y ( k ) - δ k}{δ} ,$$

where k denotes the code, δ is the step-size or least significant bit (LSB), and y(k) is the actual output of the converter given the code k. The product δk represents the ideal converter output.

Element mismatch causes both static errors and dynamic distortion. Glitches cause dynamic distortion. These errors degrade the accuracy of the reproduced signal, which is undesirable. Since any converter topology with multiple levels has element mismatch, it is a well-known problem, and several methods for the mitigation of these errors have been developed. Similarly, glitches always occur in switched converters, which is the majority of converters available. An experimental survey of these prior art methods is presented in A. A. Eielsen and A. J. Fleming, “Existing methods for improving the accuracy of digital-to-analog converters,” Review of Scientific Instruments, p. 094702, August 2017.

It is known that applying a stochastic dither signal to a static non-linearity, such as the one caused by element mismatch, can reduce the observed effects of the non-linearity. In mathematical terms; the non-linear transfer characteristic of the converter is effectively convoluted with the probability density function (PDF) of the dither signal. A convolution with a suitable PDF, such as the Gaussian distribution, has a smoothing effect on the non-linearity, like a low-pass filter, and thereby reduces the impact of the non-linearity on other signals passing through. No knowledge of the element mismatch is required, and the method has modest computational requirements. The dither is typically filtered using a high-pass filter to simplify the removal at the output. Oversampling can improve the effectiveness by providing more bandwidth for the dither but may also exacerbate problems related to element switching.

The main problem with this method is that it is difficult to remove the dither from the output, as it is distributed in frequency. Even for narrow-band dither, the dither power will leak into the useful frequency bands due to the whitening effect of the static non-linearity. The PDF of the dither will always tend to be Gaussian, as spectrally shaping the noise with linear filters causes the probability density to converge to the Gaussian distribution due to the central limit theorem. This limits the control over the smoothing effect and as well as the maximal values of the dither signal. Lastly, as the dither typically causes rapid switching, the method requires a converter with fast switching elements, equivalent to the case of dynamic element matching. This can give rise to switching glitches and, hence, the dither tends to incur additional non-linearity and distortion that undermines the method's effectiveness. In practice, stochastic dither applied for this purpose in converters, has been limited in amplitude to a few least significant bits (LSBs). The amplitude of the dither signal is limited due to the fact that the higher the dither signal amplitude is, the lower the maximum amplitude of the digital signal being converted must be and therefore the higher the noise floor on the final signal.

### SUMMARY OF THE INVENTION

According to a first aspect of the invention there is provided a digital-to-analogue converter device including:
(a) a first input configured to receive a digital signal to be converted;
(b) a second input configured to receive a digital dither signal, the digital dither signal having a predefined amplitude;
(c) a signal combining module that is configured to combine the digital dither signal with the digital signal in the digital domain to define a combined digital signal; and
(d) a digital-to-analogue converter module that is configured to process the combined digital signal and to output an analogue signal that is an analogue representation of the combined digital signal, the digital-to-analogue converter module having a predefined output amplitude range;
   wherein the predefined amplitude of the dither signal is at least 1% of the predefined output amplitude range.

Preferably, the digital dither signal is deterministic.

The predefined amplitude of the dither signal is preferably in the range of 10% to 90% of the predefined output amplitude range.

In some embodiments the predefined amplitude of the dither signal is in the range of 40% to 60% of the predefined output amplitude range.

In some embodiments the device includes:
an analogue signal modifier that is configured to modify the analogue signal to reduce effects attributable to the digital dither signal based on known properties of the digital dither signal.

In some embodiments the analogue signal modifier includes one or more of the following in any combination:
1. a low-pass filter;
2. a notch filter;
3. a signal inverter configured to process the digital dither signal in the digital domain to provide an inverted dither signal as an output wherein the inverted dither signal is the inverse of the digital dither signal, a secondary digital-to-analogue converter configured to process the inverted dither signal to provide an output that is an analogue representation of the inverted dither signal and a signal combining component for combining the outputs of the digital-to-analogue converter and the secondary digital-to-analogue converter.

In some embodiments the digital dither signal has a higher fundamental frequency than the bandwidth of the digital signal. In some embodiments the digital dither signal has a fundamental frequency at least one order of magnitude greater than the bandwidth of the digital signal.

In one embodiment the digital dither signal is indicative of a triangular wave. In another embodiment the digital dither signal is indicative of a sinusoidal wave.

In some embodiments the digital dither signal has a uniform amplitude distribution. In other embodiments the dither signal has an arbitrary amplitude distribution.

In some embodiments the second input is connected to a signal generator configured to generate the digital dither signal.

In some embodiments the device includes an amplifier for amplifying the analogue signal.

In some embodiments the device includes:
a plurality of digital-to-analogue converter modules, each module configured to receive respective digital inputs indicative of the combined digital signal and produce respective analogue signals being analogue representations of the respective digital inputs; and
a plurality of analogue signal modifiers each associated with a corresponding digital-to-analogue converter module and configured to modify the respective analogue signals and generate respective analogue conversions of the digital signal; and
an averaging module for combining the respective analogue conversions of the digital signals and generating an average analogue conversion of the digital signal.

According to a second aspect of the invention there is provided a system for digital-to-analogue conversion including:
a plurality of devices according to the first aspect;
a master input that receives a digital signal and provides the digital signal to each of the respective inputs of the plurality of devices;
an averaging module that is configured to receive the respective analogue signals from the outputs of the plurality of devices, and perform an averaging process thereby to define an averaged analogue signal; and
a master output configured to provide the averaged analogue signal.

In some embodiments a subset of the dither signals of each device is different from the remainder.

According to a third aspect of the invention there is provided a method of digital-to-analogue conversion, the method including:
receiving a digital signal to be converted;
receiving a digital dither signal, the digital dither signal having a predefined amplitude;
combining the dither signal with the digital signal in the digital domain to define a combined digital signal;
performing a digital-to-analogue conversion of the combined digital signal to output an analogue signal that is an analogue representation of the combined digital signal, the digital-to-analogue conversion process defining an output amplitude range representative of a maximum amplitude of the analogue signal; and
outputting the analogue signal;
wherein the predefined amplitude of the dither signal is at least 1% of the predefined output amplitude range.

In some embodiments the digital dither signal is deterministic.

In some embodiments the predefined amplitude of the dither signal is in the range of 10% to 90% of the predefined output amplitude range. In some embodiments the predefined amplitude of the dither signal is in the range of 40% to 60% of the predefined output amplitude range.

In some embodiments the method includes the step of:
modifying the analogue signal to reduce effects attributable to the digital dither signal based on known properties of the digital dither signal.

In some embodiments the step of modifying the analogue conversion of the combined signal includes one or more of the following in any combination:
1. low-pass filtering the analogue signal;
2. notch filtering the analogue signal;
3. providing a reference signal indicative of an inverted version of the dither signal, performing a digital-to-analogue conversion of the reference signal to output an analogue representation of the reference signal and combining the analogue representation of the reference signal with the analogue signal.

In some embodiments the dither signal has a higher fundamental frequency than the bandwidth of the digital signal. In some embodiments the dither signal has a fundamental frequency at least one order of magnitude greater than the bandwidth of the digital signal.

In one embodiment the dither signal is a triangular wave. In another embodiment the dither signal is a sinusoidal wave.

In some embodiments the dither signal has a uniform amplitude distribution. In other embodiments the dither signal has an arbitrary amplitude distribution.

As those skilled in the art will appreciate, the present invention is not limited to the embodiments and arrangements described above. Other objects of the present invention and its particular features and advantages will become more apparent from consideration of the following drawings and detailed description of the invention.

### BRIEF DESCRIPTION OF THE DRAWINGS

A preferred embodiment of the invention will now be described, by way of example only, with reference to the accompanying drawings in which:

FIG. 1 is a schematic diagram of a first embodiment of a digital-to-analogue converter device;

FIG. 2 is a circuit diagram of an exemplary DAC module;

FIG. 3 is a schematic diagram of a second embodiment of a digital-to-analogue converter device including an analogue signal modifier;

FIG. 4 is a schematic diagram of a third embodiment of a digital-to-analogue converter device;

FIG. 5A is a schematic diagram of a fourth embodiment of a digital-to-analogue converter device including a plurality of digital-to-analogue converter modules;

FIG. 5B is a schematic diagram of a fifth embodiment of a digital-to-analogue converter device including a plurality of digital-to-analogue converter modules and a plurality of analogue signal modifiers;

FIG. 6 is a schematic illustration of a system for digital-to-analogue conversion including a plurality of digital-to-analogue converter devices;

FIG. 7 is a graph of exemplary results showing the effect of dither on the element mismatch, or integral non-linearity (INL) of an off-the-shelf commercial converter;

FIG. 8 is a schematic diagram of an experimental set-up used to test performance of example embodiments of the invention;

FIG. 9 is a graph of performance gains under different experimental conditions when using a 99-Hz carrier signal;

FIG. 10 is an exemplary power spectrum produced using the experimental set-up of FIG. 8 using an input 99 Hz carrier signal with different dither configurations to highlight the effect of the HF dither;

FIG. 11 is an exemplary power spectrum produced using the experimental set-up of FIG. 8 using an input 999 Hz carrier signal with different dither configurations to highlight the effect of the HF dither; and

FIG. 12 is an exemplary power spectrum produced the experimental set-up of FIG. 8 and showing the effect of the differential amplifier (improved removal of HF dither) and channel averaging (lower noise-floor).

### DETAILED DESCRIPTION OF THE INVENTION

The following detailed description illustrates the technology by way of example, not by way of limitation of the principles of the invention. This description will enable one skilled in the art to make and use the technology, and describes several embodiments, adaptations, variations, alternatives and uses of the invention, including what is presently believed to be the best mode of carrying out the invention. One skilled in the art will recognize alternative variations and arrangements, and the present technology is not limited to those embodiments described hereafter.

Described herein are devices, systems and methods for digital-analogue conversion (DAC). In overview, the devices, systems and methods provide a means for converting a digital signal to an analogue signal.

System Level Overview

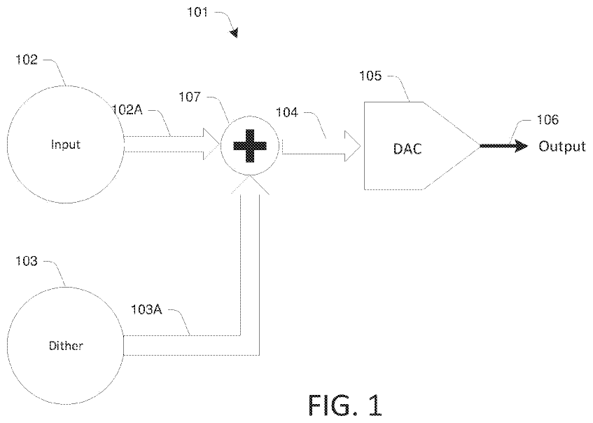

FIG. 1 is a schematic diagram for an embodiment of a digital-to-analogue converter device 101 according to the present invention. This is provided for the sake of illustration only, and it will be appreciated that embodiments of the present invention are by no means limited to the configuration shown in FIG. 1.

Device 101 includes a first input 102 for receiving a digital signal 102A that is to be converted to analogue. Device 101 also includes a second input 103 for receiving a digital dither signal 103A. Digital dither signal 103A is generated by a digital signal generator that is connected to second input 103. Digital signal generation can be performed by a number of known techniques that will be apparent to the person skilled in the art and the details of the signal generation are not described here. A combiner module 107 combines digital signal 102A with dither signal 103A thereby to define a combined digital signal 104. As each of the signals are digital in nature, this combining process occurs in the digital domain. The combined digital signal 104 is then processed by a digital to analogue converter module 105 to provide an output signal 106 that is an analogue representation of the combined digital signal 104. In this embodiment, the dither signal has a predefined amplitude of at least 1% of a predefined output amplitude range of the digital-to-analogue converter module.

In one embodiment the digital dither signal is deterministic in nature. However, in other embodiments, the digital dither signal can be at least partially random in nature.

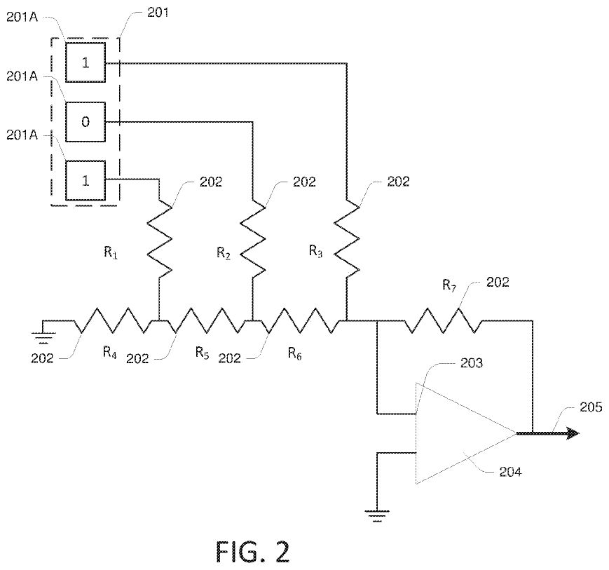

The digital to analogue converter module 105 may represent a typical off-the-shelf digital to analogue converter device. A circuit diagram of an exemplary DAC module is illustrated in FIG. 2. A binary signal 201 representing digital values is transmitted as binary voltages which are received by the input of the digital to analogue converter module. The input typically includes an array of resistors 202 of predefined resistance values arranged in a voltage dividing configuration such that each bit 201A of the digital value is received through a dedicated resistor divider. The outputs of the resistor dividers all connect to a common input terminal 203 of an amplifier 204 which outputs an analogue signal 205. The arrangement and values of the resistors in the resistor divider determine the weighting given to each bit at the input terminal of the amplifier. The analogue output of the amplifier is the analogue representation of the digital input.

In some embodiments, the dither signal may have other predefined amplitudes such as a range of 10% to 90% of the predefined output amplitude range of the digital-to-analogue converter module or a range of 40% to 60% of the predefined output amplitude range. Other embodiments may utilise dither signals with other predefined amplitudes or use a dither signal with an arbitrary amplitude range.

Referring again to FIG. 1, input 102 represents a digital interface for receiving the digital signal 102A in the form of a sequence of digital values represented by a group of binary bits. The number of bits used to represent a digital value defines the resolution of the digital signal. By way of example, a 4 bit digital signal has 16 possible digital values. The digital dither signal represents a similar sequence of digital values having digital values formed from the same or fewer numbers of bits. Similarly, input 103 represents a digital interface for receiving the digital dither signal 103A in the form of a controlled sequence of digital values represented by a group of binary bits.

Preferably, the combiner module 107 represents a digital addition function operating in the digital domain to add the respective digital values of the digital input and dither signals together. However, in other embodiments, the combiner module 107 combines the two digital signals in other ways such as using a multiplication function or a convolution function.

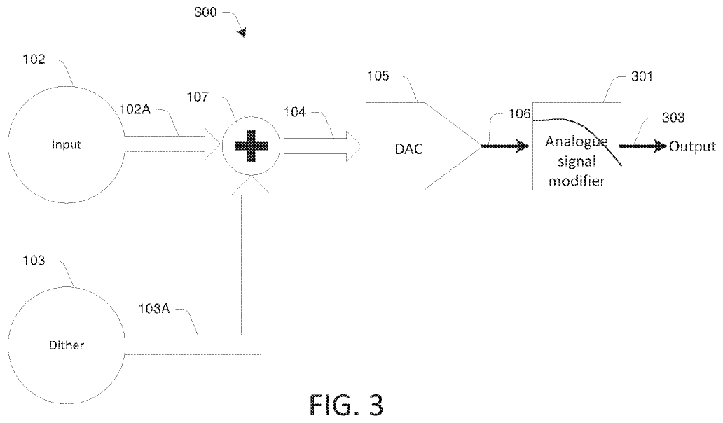

FIG. 3 depicts another embodiment device 300 of the invention which includes an analogue signal modifier 301 to modify the output analogue signal so as to substantially reduce the effects attributable to the digital dither signal 103A. In system 300, corresponding features of system 101 are given like reference numerals. In particular, the analogue signal modifier 301 reduces the component of the dither signal 103A in the output analogue signal 106 and generates a modified analogue signal 303 which is also an analogue representation of the input digital signal 102A. The analogue signal modifier 301 acts primarily based on known properties of the digital dither signal 103A such as frequency, amplitude and bandwidth.

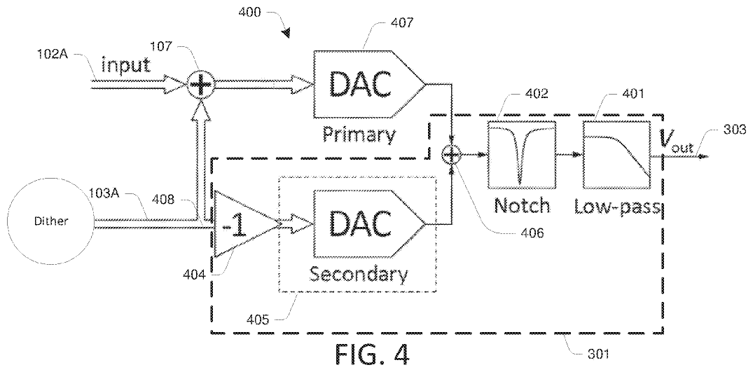

The analogue signal modifier 301 can include various components depending on the requirements and constraints of the system application. Referring now to FIG. 4, there is illustrated a device 400 wherein the analogue signal modifier 301 includes a low pass filter 401, a notch filter 402, signal inverter 404, secondary digital-to-analogue converter module 405 and an analogue signal combiner module 406 operating in combination. Analogue signal modifier 301 is designed to reduce the dither signal component of the output analogue signal 303. In system 400, the digital dither signal 103A is split or copied by a signal splitter 408 and processed by the signal inverter 404 to provide an inverse digital dither signal. The inverse digital dither signal is then processed by the secondary digital-to-analogue converter module 405 to provide an analogue representation of the inverted digital dither signal 406. The analogue representation of the inverted digital dither signal is then combined with the output of the first digital-to-analogue converter module 407 by the analogue signal combiner 406. Combining the analogue representation of the inverted digital dither signal with the analogue representation of the combined digital signal substantially reduces the component of the dither signal. In other words, the dither signal is added to the input signal of the converter, the converter is effectively linearized, and the dither is subsequently removed from the output signal. Since the dither signal is unwanted in the output signal, several methods can be used to attenuate it. Under ideal assumptions, summing two identical signals with opposite polarity should cancel the dither signal in the output. In a practical circuit, there may be a residual dither signal leftover after the subtraction; however, this can effectively be eliminated by notch filters and/or a low-pass filter.

It will be appreciated that the analogue signal modifier 301 may include several of the examples listed above in any combination.

In many practical applications, a single low-pass filter will be sufficient to attenuate the dither. Complete removal of the dither signal may not be required in applications such as audio which are insensitive to frequencies beyond the limit of hearing. A reconstruction low-pass filter should be present in a system utilizing digital-to-analogue conversion; hence, in many cases, no additional circuit would be required to implement this method.

The form of the digital dither signal used is subject to conditions and requirements imposed by the application. In many applications, the form of the digital dither signal will be selected based on the degree to which it is to be removed from the final analogue signal. That is, the degree of distortion and noise that is tolerable in the output analogue signal. For example, to facilitate the analogue signal modification in some embodiments, the fundamental frequency of the digital dither signal should be higher than the bandwidth of the input digital signal. It may be one order of magnitude greater than the bandwidth of the input digital signal or even greater depending on the nature of the application. Similarly, utilising a deterministic digital dither signal may further facilitate the analogue signal modification. Exemplary deterministic digital dither signals are signals indicative of a triangular wave, a saw tooth wave or a sinusoidal wave although it will be appreciated that other forms of deterministic signals are possible.

Other types of digital dither signal may also be used. In some embodiments it may be desirable to use a digital dither signal with a uniform amplitude distribution, while in other embodiments it may be desirable to utilise a digital dither signal with an arbitrary amplitude distribution.

In some embodiments, an analogue signal amplifier may be included to amplify the output analogue signal. The amplifier may be required in the case of a large dither signal which will necessarily reduce the maximum amplitude of the input digital signal to avoid saturating the output stage of the digital-to-analogue converter module. The amplifier can then be used to bring the analogue signal to the desired amplitude.

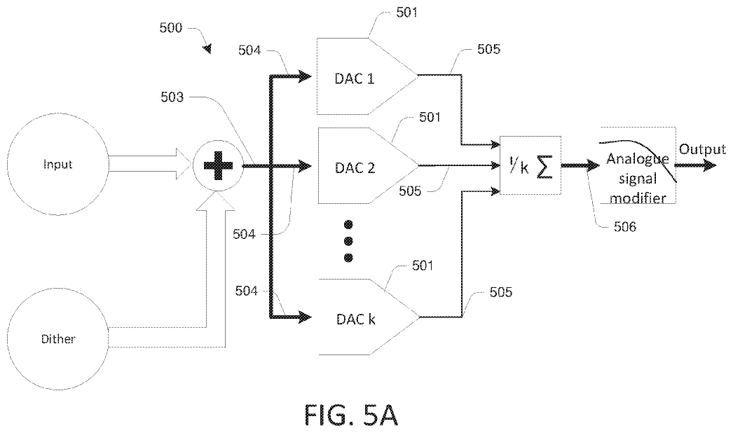

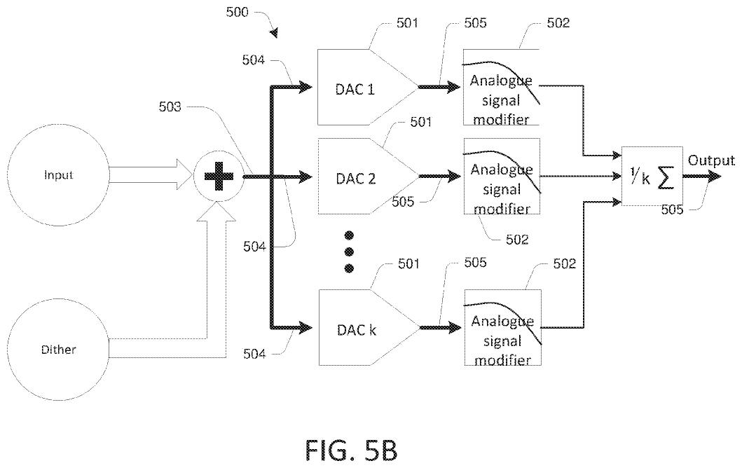

It will be appreciated that some embodiments may make use of a plurality of digital to analogue converter modules 501 as shown in device 500 of FIG. 5A. In this embodiment, the combined digital signal 503 is provided at the respective inputs 504 of the plurality of digital to analogue converter modules. Each digital to analogue converter module independently converts the combined digital signal to a respective analogue signal 505. The plurality of analogue signals, each respectively coming from one of the plurality of digital to analogue converter modules, are then averaged to yield a single analogue output 506. The single analogue output can then be modified using any of the analogue signal modifiers described above. Alternative embodiments, as shown in FIG. 5B, may include a plurality of analogue signal modifiers, each associated with one of the plurality of digital to analogue modules to modify their respective analogue signals before averaging.

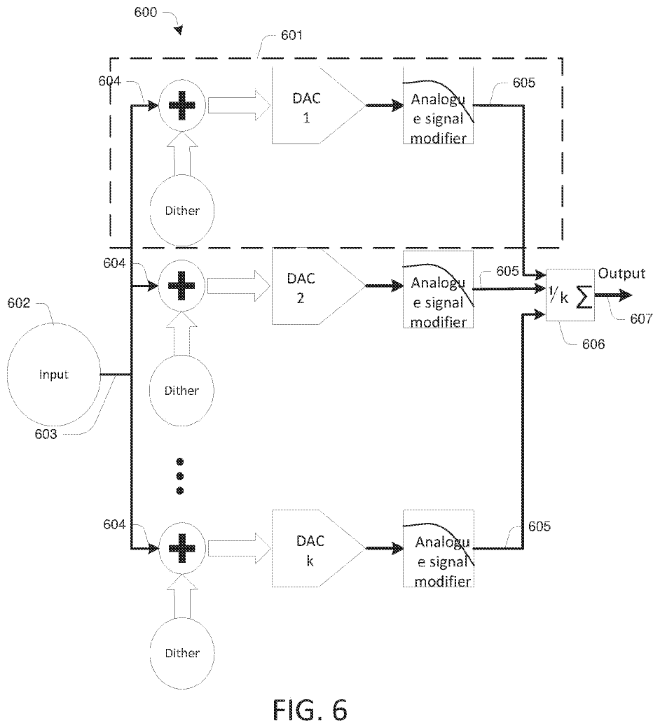

Referring now to FIG. 6, a system 600 can be formed using a plurality of digital-to-analogue converter devices 601 such as the ones shown in FIG. 1 and FIG. 2. This embodiment includes a master input 602 that receives a digital signal 603 and provides it to each of the respective inputs 604 of the plurality of digital-to-analogue converter devices. The digital-to-analogue converter devices individually operate on their respective input digital signals as described above, each respectively outputting an analogue signal 605 representative of the input digital signal. The respective analogue signals are then averaged using an averaging module 606 to define an averaged output analogue signal 607. The averaged output analogue signal 607 is then considered to be the output analogue signal which is an analogue representation of the input digital signal. It will be appreciated that an analogue signal modifier may be incorporated into each digital-to-analogue converter device, as shown in FIG. 6, may be appropriate for situations where a subset of the dither signals used in each device are different although they need not be. Alternatively, a single analogue signal modifier may be used on the output of the averaging module or, in certain applications, no analogue signal modifier is used at all. The exact configuration used will be determined by the specific requirements and constraints of the application.

Concept Overview

As mentioned above, digital-to-analogue conversion is typically based on mapping codes or numbers to specified discrete voltage or current levels. The mechanism which produces a given voltage or current level is referred to as an element. If the physical levels deviate from ideal specified levels, an error is introduced. This error is called element mismatch and is typically quantified by the INL equation in the Background section above. The desired elements are typically switched on or off to produce the desired voltage or current level in the output. The switching is imperfect, and causes glitches, which are high-frequency disturbances.

Element mismatch causes both static errors and dynamic distortion. These errors degrade the accuracy of the reproduced signal, which is undesirable. Several methods for the mitigation of these errors have been developed.

The most basic and straight-forward method for improving the accuracy of a device is to use precision components and to use fabrication techniques that preserve and improve the precision. E.g., by using very precise voltage references and resistors, the output voltage levels will physically be more accurate. For fabrication, techniques such as matching conductor lengths and ensuring uniform temperature by improved thermal coupling can be used to preserve the precision of the components. Components can be made more precise by trimming, usually by removing material mechanically by lasers, lathes, or other means. Techniques for trimming passive components that are buried and for automated trimming of components in an active circuit have all been tried. The main problems with these methods are that they are time-consuming and expensive, they cannot be applied after manufacturing, and they are difficult to use on a large scale for mass production.

Having more accurate physical output levels directly reduces element mismatch, and if having more precise physical components is practically difficult, other means can be used to achieve the same thing. Hence, the physical level calibration method can be used to coerce the actual output levels towards the ideal levels. For example, a system for adjusting the output current for each output current level of a main DAC, using an auxiliary DAC, as well as a measurement method for obtaining and storing the correction levels. Similarly, a method for redistributing the capacitance in capacitor based converters, as well as a method for measuring, determining, and storing correction configurations has been described. Another method using voltage output converters and an auxiliary converter, in addition to the main converter has also been described. In this method, the auxiliary converter is bi-polar and has very low gain, such that several of the output levels of this device falls between the step-size of the levels of the main converter. By summing the output of the two converters, the auxiliary device can then be used to adjust the levels of the main converter; improving the accuracy. The correction levels are stored in a look-up table (LUT).

The main problem with this method is the need to accurately measure the output levels or compare them with an accurate reference. The accuracy of a device using this method can only be as good as the accuracy of the device measuring the levels, e.g. a multimeter or precision analog-to-digital converter. Additionally, for a converter with many levels, it can take a long time to measure the levels. E.g., if measuring a level takes 0.1 seconds, it will take nearly 2 hours to measure all the levels of a 16-bit converter.

Physical level calibration relies on the addition calibration circuitry, e.g. for the specific method described, the auxiliary converter, and scaling and summing stages, as well as means to store a look-up table of correction values in non-volatile memory. This adds to the implementation complexity. For the method described, the correction signal is also directly dependent on the input signal, and for high-frequency input signals, this can cause rapid switching with large jumps in levels for the auxiliary converter. Rapid switching of output elements tends to excite additional non-linear dynamic effects, slewing limits and switching glitches, generating distortion in addition to the static element mismatch. Hence, this can degrade the effectiveness of the method for higher frequency input signals.

Improving the precision of the physical components and measuring and correcting the actual physical output levels of a converter is often practically difficult in mass production. Therefore, the two previous methods are seldom used in commercial devices, bar laser trimming of resistors and/or direct calibration of current sources in some expensive high-end devices. However, a method that is used in almost every commercial state-of-the-art converter currently on the market, is dynamic element matching.

Dynamic element matching is based on having redundancy in the output levels. That means having several ways of producing the same output levels. Ideally, one would then be able to produce the same level by switching on different output elements in different combinations. E.g., if the output of two 2-bit converters were to be summed together, one could produce the value 3 in two different ways, as 1+2 or as 2+1. Since each combination of levels produce different errors due to element mismatch, these errors can be randomized by continuously and randomly switching between combinations of elements that should produce the same output. Hence, a systematic error can be converted to white noise. For some dynamic element matching methods, the noise can also be spectrally shaped. Spectral shaping means that the error power is shifted to a specified frequency band, and removed by a filter on the output. This effect is most noticeable when used in conjunction with noise-shaping (in this case without digital calibration, discussed below). Oversampling (using a sample-rate higher than what is required by the Nyquist-Shannon sampling theorem) can improve the effectiveness, providing a wider frequency band to distribute the error power over, but may also exacerbate problems related to element switching.

There are two salient problems with this method. First, for the continuous and random switching of output elements to work well, it is required that the elements have good switching performance, as dynamic element matching typically incurs extremely rapid switching regardless of input signal properties. The performance of switches is mainly dependent on the attainable slew rate, and the glitch energy (the deviation from an ideal transition) generated. Both are due to non-linear effects, and cause unwanted distortions. Rapid switching tends to exacerbate the impact of these non-ideal effects, and can lead to significant performance deterioration. It should be mentioned that the most recent dynamic element matching methods add mechanisms that try to reduce the switching rate. Additionally, existing dynamic element matching methods either require the output elements to be uniform (e.g. only summing 1-bit converters), or the output levels must be distributed according to certain rules. This means that a converter utilizing dynamic element matching must have a custom-made topology. This excludes certain standard topologies, such as the Kelvin resistor-string or the R-2R resistor ladder.

Furthermore, the computational requirements for dynamic element methods can be quite high. Some encoders are fairly simple, but increasing performance typically means increased computational requirements. The most advanced methods are theoretically optimal, but cannot presently be implemented in real-time. The element redundancy requirement also poses a practical limitation, as adding more and more elements to the output stage of a converter requires a lot of area; there is a limit to how many switches that physically can fit on a chip die.

Noise-shaping with digital calibration is a modification and extension of the Δ-Σ modulator. Assuming it is possible to model the element mismatch accurately as a static non-linearity, one can use well-known techniques from control theory to suppress the mismatch error using feedback. The model used is simply the measured output levels of the converter. Using this model an error signal can be produced that describes the discrepancy between the input signal and the output signal. If the levels predicted by the model are accurate compared to the actual levels, then the error signal is a good representation of the actual error apparent in the physical output. By using this error signal in a feedback configuration, it is then possible to generate a control signal that helps to drive this error to zero. There are some physical limitations that constrict the bandwidth of the scheme, hence the error can only be suppressed in finite frequency bands. These limitations are enforced by a filter in the feedback path. This ensures the numerical stability of the scheme. The error signal, or noise, is therefore spectrally shaped by the filter; which is why it is called noise-shaping. The term digital calibration refers to the measurement of the output levels, and the use of these measured values in the digital domain, rather than the analogue domain, which is the output. The method is versatile as it can be adapted to essentially any converter topology, and it is known that it can be very effective in improving the accuracy in baseband applications (from 0 Hz to a given cut-off frequency, e.g. audio reproduction). Oversampling is essentially required for this method to work.

The main problems with the method are the need to measure the output levels which may be time consuming. Similar to physical level calibration, the process is time-consuming and error prone, where the accuracy is ultimately limited by the accuracy of the measurements. The implementation of this method may be complicated by numerical stability problems in fixed-point implementations, size constraints in floating-point implementations, and the need to store the measured levels in non-volatile memory.

In this method, the correction signal is dependent on the input signal; which is similar to physical level calibration. This implies more rapid switching as the input signal frequency increases, which decreases effectiveness due to non-ideal switching effects.

In terms of adoption in commercial devices, few devices implement physical level calibration, noise-shaping with digital calibration, or narrow-band stochastic dithering. Dynamic element matching (in combination with noise-shaping without digital calibration), on the other hand, is commonly used in commercial devices. It would seem that the convenience of not having to measure and store the output levels overcomes the disadvantage of fast switching elements and custom converter topologies. Despite the disadvantages, dynamic element matching is economical for mass production once the manufacturing process has been established. As the physical precision of the devices directly impacts performance, the manufacturing process will be optimized to produce the highest precision allowable by the techniques and equipment used, hence ‘component selection, trimming, and precision fabrication techniques’ are taken into consideration when developing the process.

Considering improvements over the current methods for mitigating element mismatch, the inventors have identified that following points seem to be most salient:
Knowledge of the non-linearity should not be required, as measuring output levels is error-prone and time-consuming, and the derived correction values must be stored.
Switching between elements should be limited to reduce the effects of additional dynamic non-linear effects, mainly due to slew-rate limitations and glitch energy.
There should be flexibility with regards to the converter topology; enabling implementation on the two most common topologies: The Kelvin resistor string, and the R-2R resistor ladder.
It is beneficial if the computational requirements are low, as it simplifies the implementation and reduces costs.

The method proposed here, aligns well with these requirements: It does not require any knowledge of the non-linearity, the switching rate is deterministic and adjustable, and it can be implemented on any multi-level topology, including the Kelvin resistor string, and the R-2R resistor ladder. The computational requirements are limited to signal generation and oversampling.

The method is based on the fact that a static non-linear function n(·) can, by the application of a suitable periodic dither, be approximated by a smoothed non-linear function N(·), where ∥N∥_{∞}≤∥n∥_{∞}; hence reducing the effects caused by the non-linearity. The effective smoothed non-linearity N(·) is determined by the original non-linearity n(·) and the amplitude distribution function of the dither. The smoothed non-linear function is defined by the Lebesgue-Stieltjes integral [18] [19]

N(x) [symbol] n(x+v)dFₚ(v),

where Fₚ(v) denotes the amplitude distribution function of the dither signal p. The method relies on the approximate equivalence of the above Lebesgue-Stieltjes integral and the time-average over one period τ of the periodic dither. The approximation is mainly dependent on the frequency of the dither 1/τ, hence it is termed high-frequency dither. The higher the frequency, the better the approximation. In practice the frequency does not have to be significantly higher than the desired signal bandwidth for the approximation error to be negligible. However, oversampling is required in some circumstances in order to maintain sufficient separation in frequency between the input signal and the dither signal, as well as to ensure that the dither signal is reproduced to a good approximation.

Non-linearities of almost any form will be smoothed by the dithering method. Hence, no knowledge of the non-linearity is required. The switching rate is adjusted by the frequency of the dither. Any converter topology with multiple levels can be dithered.

It will be appreciated that embodiments of the invention described above provide improved digital to analogue conversion over existing known prior art systems and methods. Preferred embodiments of the present invention provide a novel linearization method and apparatus for reducing the non-linearity associated with element mismatch in digital-to-analogue converters. The apparatus and method in the preferred embodiment are based on applying a large, periodic, high-frequency dither signal to the desired signal in the digital domain. The dither signal will cause the desired signal to sweep over several voltage levels of the digital-to analogue converter module effectively averaging out the mismatches. Since the dither is both high in frequency, deterministic, and narrow-band, it can be efficiently removed in the output by low-pass filters, notch filters and/or subtraction of the dither signal from the output by using an auxiliary converter and summing or subtracting stage. The noise-floor can be improved by averaging several converters, increasing overall performance. The frequency of the dither can be adjusted to avoid rapid switching, reducing problems with output elements with non-negligible non-linear dynamic effects, e.g. elements with low slew-rates and excessive glitch energy. No knowledge of the element mismatch is required, and the method has negligible computational requirements (only signal generation) and is suitable for any converter topology that can produce multiple output levels.

Results from an Example Physical Implementation

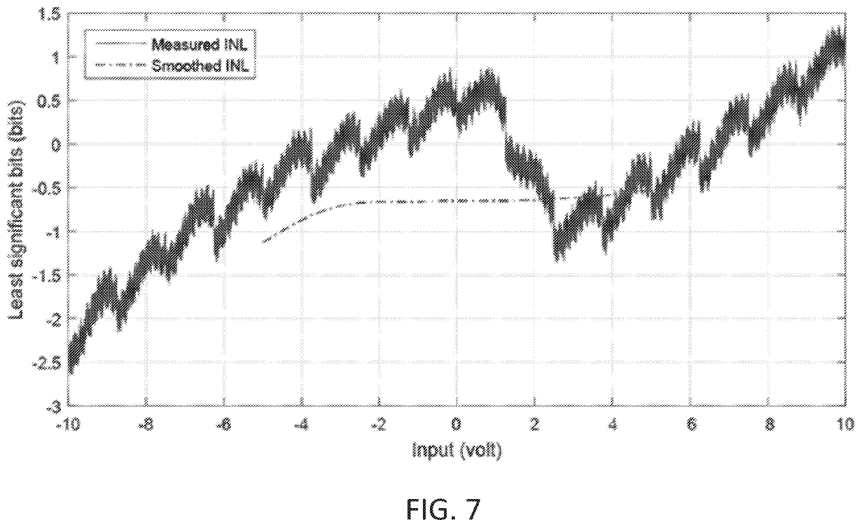

The effect of dither on the element mismatch, or integral non-linearity (INL) of an off-the-shelf commercial converter is demonstrated in FIG. 7. The INL was measured using a precision multimeter, and the Lebesgue-Stieltjes integral (1) was evaluated when using a dither signal with uniform distribution (e.g. a triangle-wave). As can be seen, the INL has been significantly reduced.

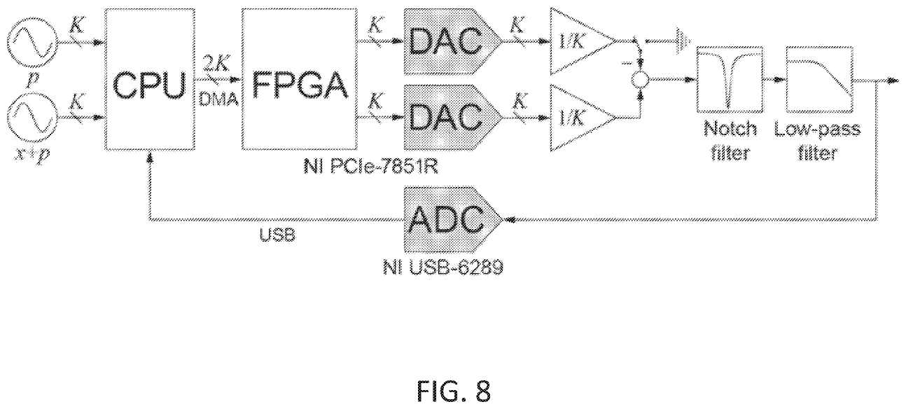

In order to demonstrate the effectiveness of the method, the experimental set-up in FIG. 8 was used. A National Instruments PCIe-7851R system was used to provide eight 16-bit converter channels with a sampling rate of up to 1 MS/s. The converter channels were controlled via the onboard field-programmable gate array (FPGA), which allows streaming of eight 1-MHz 16-bit wide signals using direct memory access (DMA) from a computer (CPU) running the National Instruments LabView software. The CPU was used to generate the carrier x and a triangle-wave dither p.

The outputs of the converters were summed and scaled using a summing circuit in order to obtain a reduction of stochastic noise. A differential stage was used to subtract the dither. A notch filter with center frequency at the fundamental frequency of the dither, as well as a low-pass filter with a 25 kHz cut-off frequency was also used to attenuate the residual dither signal after the differential stage.

A set of experiments were conducted in order to assess the performance improvement that can be achieved using the dither, as well as channel averaging and dither subtraction. The experiments were conducted using four different configurations of the set-up in FIG. 8:

1. Using a single channel, K=1, for the carrier and dither with the inverting input of the differential amplifier grounded.

2. Using a single channel, K=1, for the carrier and HF dither, and single channel for the HF dither with the inverting input of the differential amplifier connected.

3. Using four channels, K=4, for the carrier and dither with the inverting input of the differential amplifier grounded.

4. Using four channels, K=4, for the carrier and HF dither, and four channels for the HF dither with the inverting input of the differential amplifier connected.

In every case the output of the differential amplifier was filtered by the notch and low-pass filter.

The output spectra were measured using a National Instruments USB-6289. It contains an Analog Devices AD7674 18-bit successive approximation analog-to-digital converter (ADC). This ADC has sufficient linear performance, with a spurious-free dynamic range (SFDR) of 120 dBFS for the carrier frequencies considered here. A sampling rate of 625 kS/s was used. The power spectra were generated using power spectrum estimation in LabView, using a frequency resolution of 1 Hz, at least 100 averages, and a Kaiser window with window parameter α=38.

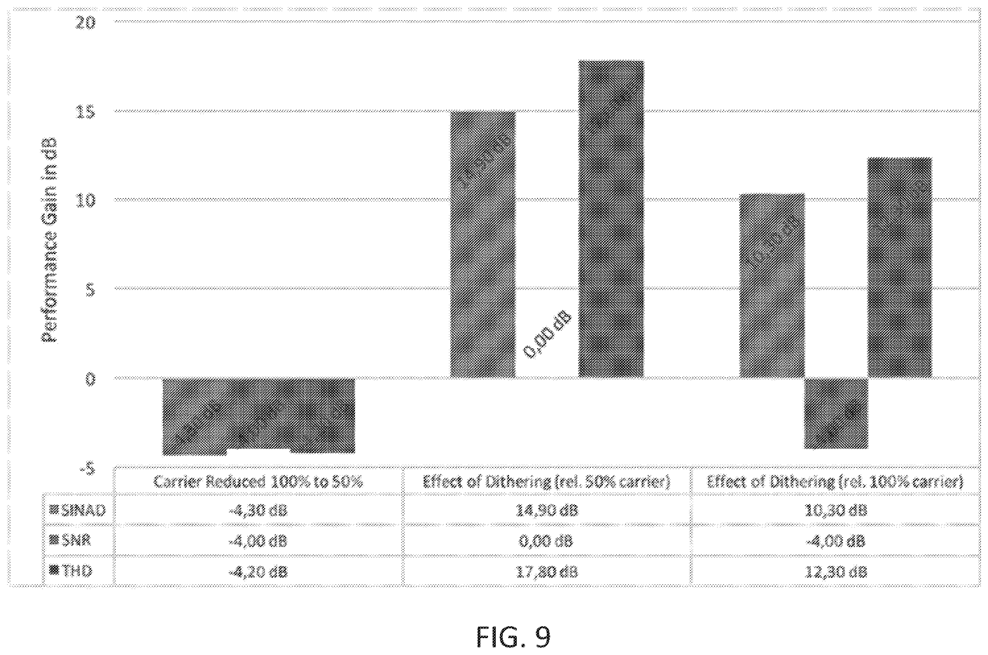

All the measured performance results are summarized in Table 1. A chart showing the main effect and performance gains for the method using a 99-Hz carrier is shown in FIG. 9. The results are summarized using the following standard metrics: The signal-to-noise ratio (SNR), total-harmonic-distortion (THD), signal-to-noise-and-distortion ratio (SINAD), and effective-number-of-bits (ENOB).

TABLE 1

| Exp. | Exp. | Carrier | | Carrier | Dither | | | | | | |
|---|---|---|---|---|---|---|---|---|---|---|---|
| No. | Config. | Freq. | | Amp. | Amp. | SINAD | | ENOB | SNR | THD | |
| 1 | N | 99 | Hz | 100% | 0% | 93.4 | dBc | 15.2 bit | 111 dB | −93.4 | dBc |
| 2 | N | 99 | Hz | 50% | 0% | 89.1 | dBc | 14.5 bit | 107 dB | −89.2 | dBc |
| 3 | N | 99 | Hz | 50% | 50% | 104 | dBc | 17.0 bit | 107 dB | −107 | dBc |
| 4 | N + D | 99 | Hz | 50% | 50% | 102 | dBc | 16.7 bit | 104 dB | −106 | dBc |
| 5 | N + Av | 99 | Hz | 100% | 0% | 94.7 | dBc | 15.4 bit | 113 dB | −94.7 | dBc |
| 6 | N + Av | 99 | Hz | 50% | 0% | 90.7 | dBc | 14.8 bit | 110 dB | −90.7 | dBc |
| 7 | N + D + Av | 99 | Hz | 50% | 50% | 105 | dBc | 17.2 bit | 109 dB | −107 | dBc |
| 8 | N | 999 | Hz | 100% | 0% | 94.2 | dBc | 15.3 bit | 111 dB | −94.2 | dBc |
| 9 | N | 999 | Hz | 50% | 0% | 89.4 | dBc | 14.6 bit | 107 dB | −89.4 | dBc |
| 10 | N | 999 | Hz | 50% | 50% | 100 | dBc | 16.4 bit | 106 dB | −102 | dBc |
| 11 | N + D | 999 | Hz | 50% | 50% | 99.7 | dBc | 16.3 bit | 104 dB | −102 | dBc |
| 12 | N + Av | 999 | Hz | 100% | 0% | 94.7 | dBc | 15.4 bit | 113 dB | −94.8 | dBc |
| 13 | N + Av | 999 | Hz | 50% | 0% | 90.0 | dBc | 14.7 bit | 110 dB | −90.1 | dBc |
| 14 | N + D + Av | 999 | Hz | 50% | 50% | 102 | dBc | 16.7 bit | 108 dB | −103 | dBc |

Filter Configurations (see FIG. 8)
N Notch filter (1 channel for carrier and HF dither)
N + D Notch filter and differential amplifier (1 channel for carrier and HF dither and 1 channel for HF dither)
N + Av Notch filter and channel averaging (4 channels for carrier and HF dither)
N + D + Av Notch filter, differential amplifier, and channel averaging (4 channels for carrier and HF dither and 4 channels for HF dither)

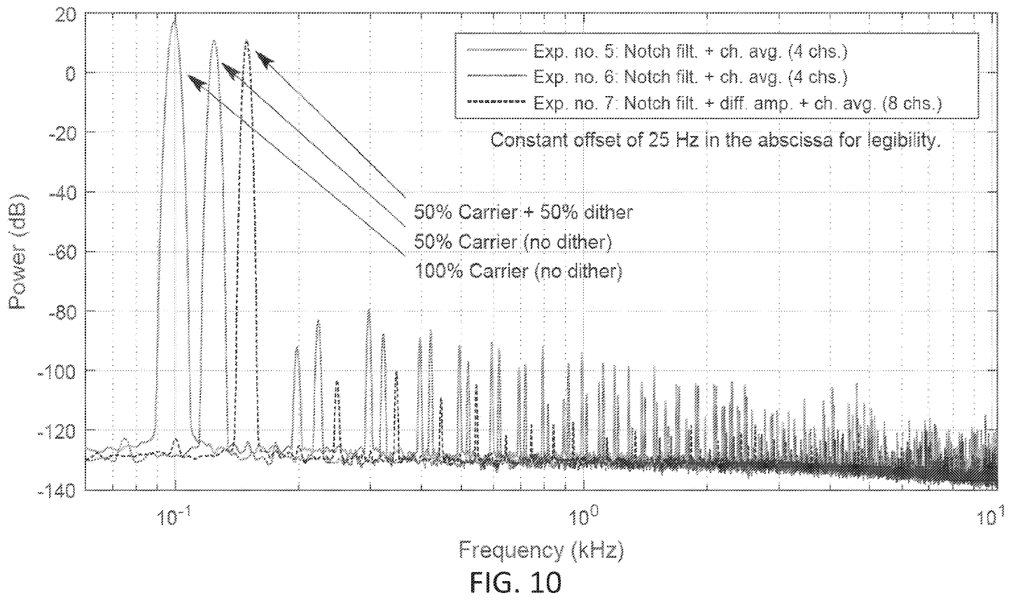

The effect of the dither is illustrated in by the power spectrum in FIG. 10. This shows the actual performance gain using a fair comparison to the original un-dithered case. The response from experiment no. 5, using a 100%-amplitude carrier at 99 Hz, is compared to the response from experiment no. 7, when using a 50%-amplitude carrier at 99 Hz and a 50%-amplitude dither at 50 kHz. It is apparent that the harmonic distortion is reduced. The performance gains in FIG. 10 are shown graphically in FIG. 9. The 1st column of FIG. 9 shows a reduction in all metrics due to the carrier signal being reduced from 100% to 50%. The 2^{nd} column shows the performance gains when adding a 50% high-frequency triangle-wave dither to the input. There is a remarkable gain of 17.8 dB in THD. This is solely due to the improved linearity of the converter (resulting in reduced harmonic distortion). The 3^{rd} column shows actual performance gains compared to the case when using a 100% carrier. It can be seen that the improvement in SINAD is 10.3 dB, even though the carrier amplitude has been reduced by 6.02 dB. Without the dither the result in the 1^{st} column would have been obtained, but due to the dither, the linearity improvement yields a remarkable gain in SINAD and THD, since the harmonic distortion is significantly reduced.

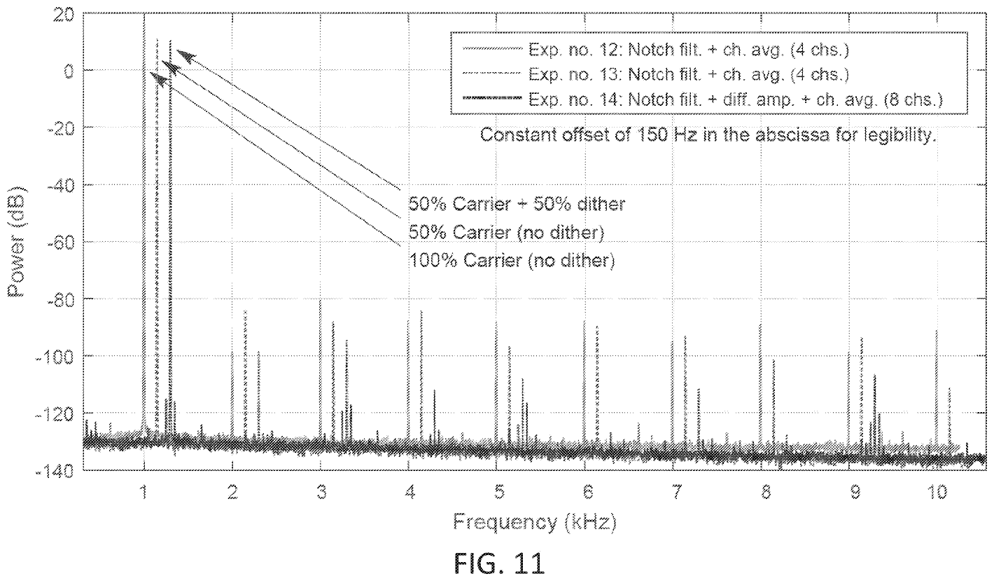

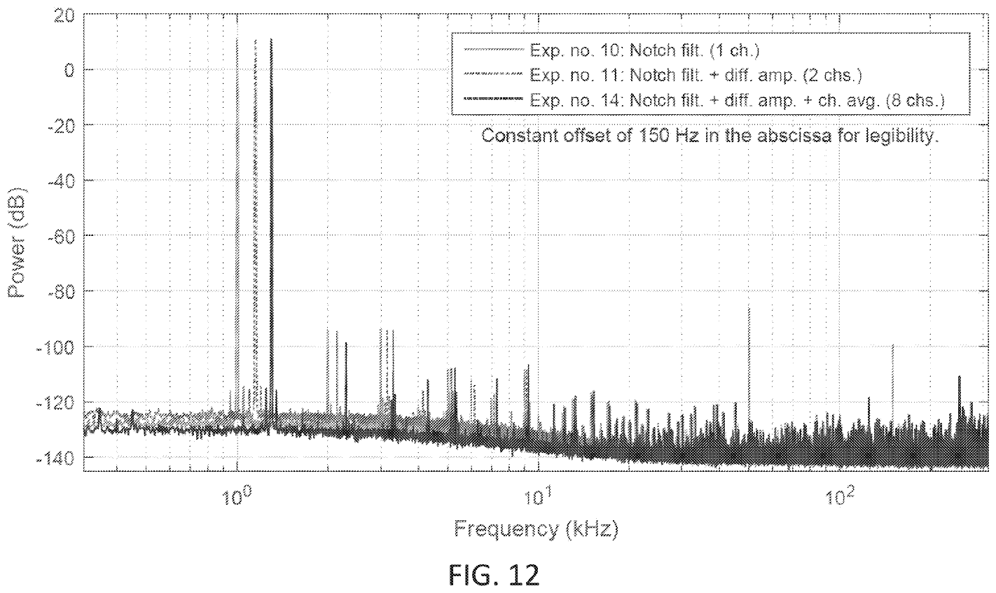

Other conclusions can be drawn from the dataset in FIG. 11 and FIG. 12: In particular, the dither subtraction removes more of the high-frequency dither components, but deteriorates the noise floor. By using channel averaging, the noise-floor can be improved.

Interpretation

Throughout this specification, use of the terms “element” or “module” are intended to mean either a single unitary component or a collection of components that combine to perform a specific function or purpose.

Unless specifically stated otherwise, as apparent from the following discussions, it is appreciated that throughout the specification discussions utilizing terms such as “processing,” “computing,” “calculating,” “determining”, analyzing” or the like, refer to the action and/or processes of a computer or computing system, or similar electronic computing device, that manipulate and/or transform data represented as physical, such as electronic, quantities into other data similarly represented as physical quantities.

Reference throughout this specification to “one embodiment”, “some embodiments” or “an embodiment” means that a particular feature, structure or characteristic described in connection with the embodiment is included in at least one embodiment of the present disclosure. Thus, appearances of the phrases “in one embodiment”, “in some embodiments” or “in an embodiment” in various places throughout this specification are not necessarily all referring to the same embodiment. Furthermore, the particular features, structures or characteristics may be combined in any suitable manner, as would be apparent to one of ordinary skill in the art from this disclosure, in one or more embodiments.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

It should be appreciated that in the above description of exemplary embodiments of the disclosure, various features of the disclosure are sometimes grouped together in a single embodiment, Fig., or description thereof for the purpose of streamlining the disclosure and aiding in the understanding of one or more of the various inventive aspects. This method of disclosure, however, is not to be interpreted as reflecting an intention that the claims require more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those skilled in the art. For example, in the following claims, any of the claimed embodiments can be used in any combination.

In the description provided herein, numerous specific details are set forth. However, it is understood that embodiments of the disclosure may be practiced without these specific details. In other instances, well-known methods, structures and techniques have not been shown in detail in order not to obscure an understanding of this description.

Similarly, it is to be noticed that the term coupled, when used in the claims, should not be interpreted as being limited to direct connections only. The terms “coupled” and “connected,” along with their derivatives, may be used. It should be understood that these terms are not intended as synonyms for each other. Thus, the scope of the expression a device A coupled to a device B should not be limited to devices or systems wherein an output of device A is directly connected to an input of device B. It means that there exists a path between an output of A and an input of B which may be a path including other devices or means. “Coupled” may mean that two or more elements are either in direct physical, electrical or optical contact, or that two or more elements are not in direct contact with each other but yet still co-operate or interact with each other.

Thus, while there has been described what are believed to be the preferred embodiments of the disclosure, those skilled in the art will recognize that other and further modifications may be made thereto without departing from the spirit of the disclosure, and it is intended to claim all such changes and modifications as fall within the scope of the disclosure. For example, any formulas given above are merely representative of procedures that may be used. Functionality may be added or deleted from the block diagrams and operations may be interchanged among functional blocks. Steps may be added or deleted to methods described within the scope of the present disclosure.

1. A digital-to-analogue converter device comprising:
a) a first input configured to receive a digital signal to be converted;
b) a second input configured to receive a digital dither signal, the digital dither signal having a predefined amplitude;
c) a signal combining module that is configured to combine the digital dither signal with the digital signal in the digital domain to define a combined digital signal; and
d) a digital-to-analogue converter module that is configured to process the combined digital signal and to output an analogue signal that is an analogue representation of the combined digital signal, the digital-to-analogue converter module having a predefined output amplitude range;
wherein the predefined amplitude of the dither signal is at least 1% of the predefined output amplitude range.

2. The device according to claim 1 wherein the digital dither signal is deterministic.

3. The device according to claim 1 wherein the predefined amplitude of the dither signal is in the range of 10% to 90% of the predefined output amplitude range.

4. The device according to claim 3 wherein the predefined amplitude of the dither signal is in the range of 40% to 60% of the predefined output amplitude range.

5. The device according to claim 1 comprising:
an analogue signal modifier that is configured to modify the analogue signal to reduce effects attributable to the digital dither signal based on known properties of the digital dither signal.

6. The device according to claim 5 wherein the analogue signal modifier includes one or more of the following in any combination:
a) a low-pass filter;
b) a notch filter;
c) a signal inverter configured to process the digital dither signal in the digital domain to provide an inverted dither signal as an output wherein the inverted dither signal is the inverse of the digital dither signal, a secondary digital-to-analogue converter configured to process the inverted dither signal to provide an output that is an analogue representation of the inverted dither signal and a signal combining component for combining the outputs of the digital-to-analogue converter and the secondary digital-to-analogue converter.

7. The device according to claim 1 wherein the digital dither signal has a higher fundamental frequency than the bandwidth of the digital signal.

8. The device according to claim 1 wherein the digital dither signal has a fundamental frequency at least one order of magnitude greater than the bandwidth of the digital signal.

9. The device according to claim 1 wherein the digital dither signal is indicative of a triangular wave.

10. The device according to claim 1 wherein the digital dither signal is indicative of a sinusoidal wave.

11. The device according to claim 1 wherein the digital dither signal has a uniform amplitude distribution.

12-14. (canceled)

15. The device according to claim 5 comprising:
a plurality of digital-to-analogue converter modules, each module configured to receive respective digital inputs indicative of the combined digital signal and produce respective analogue signals being analogue representations of the respective digital inputs;
a plurality of analogue signal modifiers each associated with a corresponding digital-to-analogue converter module and configured to modify the respective analogue signals and generate respective analogue conversions of the digital signal; and
an averaging module for combining the respective analogue conversions of the digital signals and generating an average analogue conversion of the digital signal.

16. A system for digital-to-analogue conversion comprising:
a plurality of digital-to-analogue converter devices according to claim 1;
a master input that receives a digital signal and provides the digital signal to each of the respective inputs of the plurality of devices;
an averaging module that is configured to receive the respective analogue signals from the outputs of the plurality of devices, and perform an averaging process thereby to define an averaged analogue signal; and
a master output configured to provide the averaged analogue signal.

17. The system according to claim 13 wherein a subset of the dither signals of each device is different from the remainder.

18. A method of digital-to-analogue conversion, the method comprising:
receiving a digital signal to be converted;
receiving a digital dither signal, the digital dither signal having a predefined amplitude;
combining the dither signal with the digital signal in the digital domain to define a combined digital signal;
performing a digital-to-analogue conversion of the combined digital signal to output an analogue signal that is an analogue representation of the combined digital signal, the digital-to-analogue conversion process defining an output amplitude range representative of a maximum amplitude of the analogue signal; and
outputting the analogue signal;
wherein the predefined amplitude of the dither signal is at least 1% of the predefined output amplitude range.

19. The method according to claim 15 wherein the digital dither signal is deterministic.

20. The method according to claim 15 wherein the predefined amplitude of the dither signal is in the range of 10% to 90% of the predefined output amplitude range.

21. The method according to claim 17 wherein the predefined amplitude of the dither signal is in the range of 40% to 60% of the predefined output amplitude range.

22. The method according to claim 15 including the step of:
modifying the analogue signal to reduce effects attributable to the digital dither signal based on known properties of the digital dither signal.

23. The method for digital-to-analogue conversion according to claim 19 wherein the step of modifying the analogue conversion of the combined signal includes one or more of the following in any combination:
a) low-pass filtering the analogue signal;
b) notch filtering the analogue signal;
c) providing a reference signal indicative of an inverted version of the dither signal, performing a digital-to-analogue conversion of the reference signal to output an analogue representation of the reference signal and combining the analogue representation of the reference signal with the analogue signal.

24-29. (canceled)
